(19) United States
(12) Patent Application Publication
(10) Pub. No.: US 2018/0317327 A1
(43) Pub. Date: Nov. 1, 2018

(54) METHODS OF FORMING SEGMENTED VIAS FOR PRINTED CIRCUIT BOARDS

(71) Applicant: Sanmina Corporation, San Jose, CA (US)

(72) Inventors: Shinichi IKETANI, Sunnyvale, CA (US); Dale KERSTEN, Ben Lomond, CA (US)

(21) Appl. No.: 15/963,980

(22) Filed: Apr. 26, 2018

Related U.S. Application Data
(63) Continuation of application No. 14/574,138, filed on Dec. 17, 2014, now abandoned.
(60) Provisional application No. 61/917,262, filed on Dec. 17, 2013.

(51) Int. Cl. H05K 3/42

(52) U.S. Cl. CPC H05K 3/429; H05K 2203/0713; H05K 2201/09645; Y10T 29/49165

(57) ABSTRACT

Novel methods for forming a printed circuit board (PCB) having one or more segmented vias are provided, including improved methods of removing the catalyst after the plating process when forming a segmented via in the PCB. After the electroless plating, excess catalyst on the surface of the plating resist is removed using a catalyst remover, such as an acidic solution that includes at least nitrite or nitrite ion and halogen ion, or the catalyst remover may be an etchant for plating resist, such as alkaline permanganate compound solution or plasma gas comprising at least one of oxygen, nitrogen, argon and tetrafluoromethane, or a mixture of at least two of these gasses. After removal of the excess catalyst, electrolytic plating is then applied to the through holes and the outer layer circuit or signal traces are formed. That is, the etching of paths on the conductive foils/layers of the core structure.

### CLAIM OF PRIORITY

The present application for patent claims priority to U.S. Provisional Application No. 61/917,262 entitled “Methods of Forming Segmented Vias for Printed Circuit Boards”, filed Dec. 17, 2013, which is hereby expressly incorporated by reference.

### FIELD OF THE INVENTION

The present disclosure relates to printed circuit boards (PCBs), and more particularly, to methods of forming segmented vias in a printed circuit board (PCB).

### BACKGROUND

Consumers are increasingly demanding both faster and smaller electronic products. The use of PCBs has grown enormously as new electronic applications are marketed. A PCB is formed by laminating a plurality of conducting layers with one or more non-conducting layers. As the size of a PCB shrinks, the relative complexity of its electrical interconnections grows.

A via structure is traditionally used to allow signals to travel between layers of a PCB. The plated via structure is a plated hole within the PCB that acts as a medium for the transmission of an electrical signal. For example, an electrical signal may travel through a trace on one layer of the PCB, through the plated via structure's conductive material, and then into a second trace on a different layer of the PCB.

FIG. 1 illustrates a PCB 100 with a plated via structure 130 formed through a plating resist 170. The PCB 100 includes conducting layers 110a-110e separated by dielectric layers 120a-120e. The plated via structure 130 is plated with a seed conductive material 190 (i.e. a catalyst) and a further coating of conductive material 192. The plated via 130 is partitioned into a plurality of electrically isolated portions (130a, and 130b) by selectively depositing plating resist in a sub-composite structure for making the PCB stackup. Through-holes are drilled through the PCB stackup through conductive layers, dielectric layers and through the plating resist.

The via 130 allows an electrical signal 160 to transmit from one trace 140 or component mounting pad on a first conducting layer 110a to another trace 150 on a second conducting layer 110b of the PCB 100 by traversing the isolated portion 130a of the via 130. Similarly, the isolated portion 130b of the via 130 allows another electrical signal 162 to transmit to a trace 180 without interfering with the signal 160.

The plating resist 170 limits the deposition of, or deactivates, the catalyzing material 190 and prevents conductive material 192 within the via structure 130 at the conducting layer 110d. As a result, the via 130 is partitioned into the electrically isolated portions 130a, and 130b. Consequently, the electric signal 160 travels from the first conducting layer 110a to the second conducting layer 110c without signal integrity being degraded through interference caused by electrically isolated portion 130b.

FIG. 2 (comprising FIGS. 2A and 2B) illustrates a method for forming a PCB having one or more segmented vias. First, a first core or sub-composite structure, having a first dielectric core layer sandwiched between a first conductive layer and a second conductive layer, is formed 202. At least one conductive layer of the first core or sub-composite structure may be etched to form via pads, antipads, and/or electrical traces 204. For instance, such etching may serve to form electrical paths to/from points where vias are to be formed. A first plating resist material may then be deposited on at least one surface of the first core or sub-composite structure 206.

Optionally, a second core or sub-composite structure, having a second dielectric core layer sandwiched between a third conductive layer and a fourth conductive layer, is formed 208. At least one conductive layer of the second core or sub-composite structure may be etched to form via pads, antipads, and/or electrical traces 210. For instance, such etching may serve to form electrical paths to/from points where vias are to be formed. A second plating resist material may then be deposited on at least one surface of the second core or sub-composite structure 212.

The first core or sub-composite structure and second core or sub-composite structure may then be laminated with at least one dielectric layer in between, forming a PCB stackup 214. Through holes are drilled through the PCB stackup through conductive layers, dielectric layers and through the plating resist 216. Next, a seeding conductive material, such as electroless copper plating, is applied to the one or more through holes 218.

Electrolytic plating is applied to the one or more through holes 220. Then the outer layer circuit or signal traces are then formed 222. That is, the etching of paths on the conductive foils/layers of the core structure.

The electroless copper provides the initial conductivity path to allow for additional electrolytic copper plating of the barrel of each through hole in the stackup. The seed chemistry (catalyst) deposits on the surface of the through hole wall and although the plating resist is designed to prevent copper deposition on the plating resist, some of the catalyst may still be deposited on the plating resist. Catalyst remaining on the surface of the through hole after plating can result in poor insulation (high resistance short, electromigration) and burly plating. Consequently, there is a need for improved methods for removing the catalyst after the plating process when forming a segmented via in a printed circuit board.

### SUMMARY

The following presents a simplified summary of one or more implementations in order to provide a basic understanding of some implementations. This summary is not an extensive overview of all contemplated implementations, and is intended to neither identify key or critical elements of all implementations nor delineate the scope of any or all implementations. Its sole purpose is to present some concepts of one or more implementations in a simplified form as a prelude to the more detailed description that is presented later.

According to one feature, a method for making a printed circuit board having a segmented plated through hole is provided. The method includes forming a core or sub-composite structure; selectively depositing at least one plating resist on a dielectric layer within the core or sub-composite structure or external to the core or sub-composite structure; forming one or more through holes through the core or sub-composite structure and the plating resist; and applying a catalyzing material to an interior surface of the one or more through holes, the interior surface having a laminate portion and a plating resist portion where only the laminate portion is coated with a conductive material; applying electroless plating to the one or more through holes; removing the catalyzing material from the plating resist portion using a catalyst remover; applying electrolytic plating to the one or more through holes; and forming an outer layer circuit on the external conductive layers.

According to an aspect, the catalyzing material is palladium or a palladium derivative and the catalyst remover is an acidic solution and wherein the acidic solution includes at least nitrite or nitrite ion and halogen ion.

According to another one aspect, the catalyst remover is an etchant for plating resist and the etchant is an alkaline permanganate compound solution. The etchant may be plasma gas wherein the plasma gas includes at least one of oxygen, nitrogen, argon and tetrafluoromethane.

According to another feature, a method for making a printed circuit board having a segmented plated through hole is provided. The method includes forming a core or sub-composite structure; selectively depositing at least one plating resist on a dielectric layer within the core or sub-composite structure or external to the core or sub-composite structure; forming a through hole through the core or sub-composite structure and the plating resist; applying a catalyzing material to an interior surface of the one or more through holes, the interior surface having a laminate portion and a plating resist portion where only the laminate surface is to be coated with a conductive material applying metal plating to the one or more through holes; removing the catalyzing material from the plating resist portion using a catalyst remover; and forming an outer layer circuit on the conductive layers of the first core.

According to one aspect, the catalyzing material is palladium or a palladium derivate.

According to another aspect, the catalyst remover is an acidic solution and wherein the acidic solution includes at least nitrite or nitrite ion and halogen ion.

According to yet another aspect, the catalyst remover is an etchant for plating resist.

According to yet another aspect, the etchant is an alkaline permanganate compound solution.

According to yet another aspect, the etchant is plasma gas and wherein the plasma gas includes at least one of oxygen, nitrogen, argon and tetrafluoromethane.

According to yet another feature, a method for making a printed circuit board having a segmented plated through hole is provided. The method includes forming a core or sub-composite structure; selectively depositing at least one plating resist on a dielectric layer within the core or sub-composite structure or external to the core or sub-composite structure; forming a through hole through the core or sub-composite structure and the plating resist; and applying a catalyzing material to an interior surface of the one or more through holes, the interior surface having a laminate portion and a plating resist portion where the laminate surface is to be coated with a conductive material and the plating resist portion is not to be plated with a conductive material; applying metal plating to the one or more through holes; forming an outer layer circuit on the conductive layers of the first core; and removing the catalyzing material from the plating resist portion and dielectric material surface using a catalyst remover.

According to one aspect, the catalyzing material is palladium or a palladium derivate.

According to another aspect, the catalyst remover is an acidic solution.

According to yet another aspect, the acidic solution includes at least nitrite or nitrite ion and halogen ion.

According to yet another aspect, the catalyst remover is an etchant for plating resist.

According to yet another aspect, the etchant is an alkaline permanganate compound solution.

According to yet another aspect, the etchant is plasma gas and wherein the plasma gas includes at least one of oxygen, nitrogen, argon and tetrafluoromethane.

### BRIEF DESCRIPTION OF THE DRAWINGS

FIG. 1 illustrates a PCB with a plated via structure formed through a plating resist.

FIG. 2 (comprising FIGS. 2A and 2B) illustrates a method for forming a PCB having one or more segmented vias.

FIG. 3 illustrates a common catalyzing process printed circuit board manufacturing.

FIG. 4 illustrates an example of excess catalyst particles on the surface of a PCB.

FIG. 5 (comprising FIGS. 5A and 5B) illustrates a method for forming a PCB having one or more segmented vias, according to one aspect of the present invention.

FIG. 6 (comprising FIGS. 6A and 6B) illustrates a method for forming a PCB having one or more segmented vias, according to one aspect of the present invention.

FIG. 7 (comprising FIGS. 7A and 7B) illustrates a method for forming a PCB having one or more segmented vias, according to one aspect of the present invention.

FIG. 8 illustrates cross-sectional view of a PCB stackup having a single plating resist.

FIG. 9 illustrates cross-sectional view of a PCB stackup having more than one plating resists.

FIG. 10 illustrates a cross-sectional view of a through hole in a printed circuit board where residual catalyst has been deactivated.

FIG. 11 illustrates the cross-sectional view of the through hole in a printed circuit board of FIG. 10 where the residual catalyst is removed.

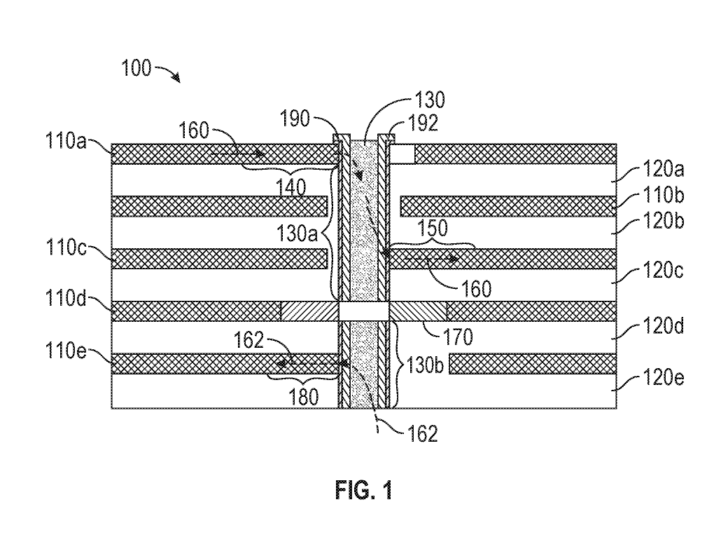

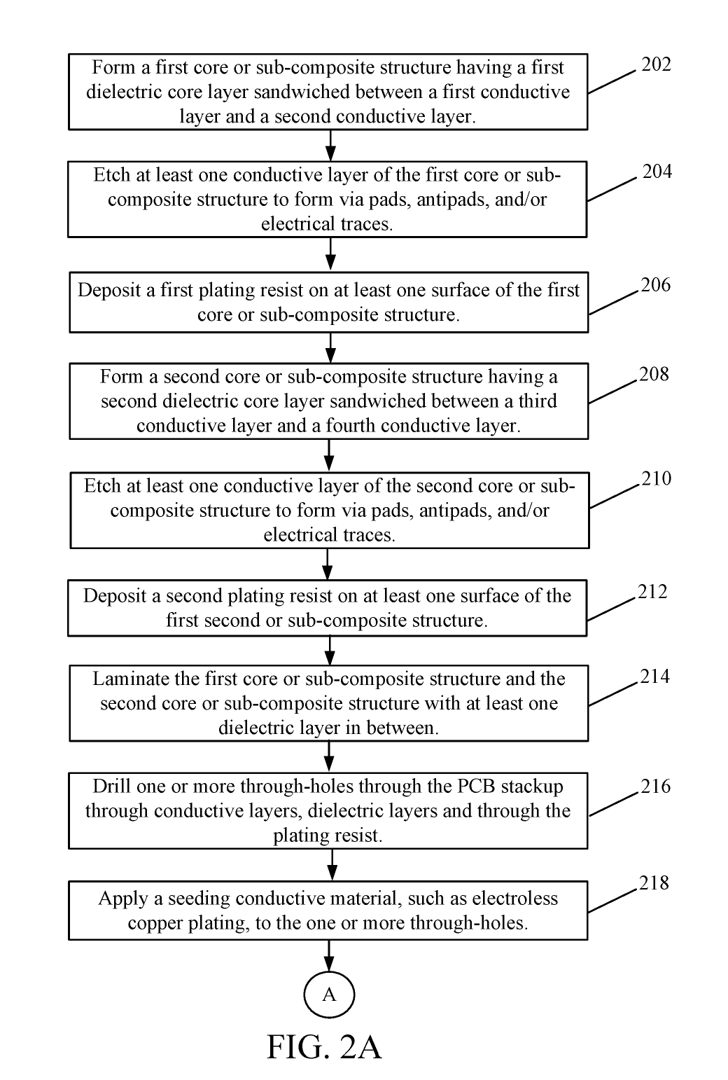

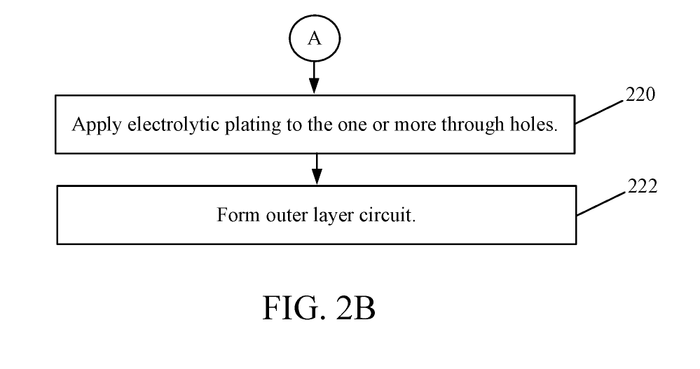

### DETAILED DESCRIPTION OF THE INVENTION

In the following detailed description of the present disclosure, numerous specific details are set forth in order to provide a thorough understanding of the disclosure. However, the disclosure may be practiced without these specific details. In other instances, well known methods, procedures, and/or components have not been described in detail so as not to unnecessarily obscure aspects of the disclosure.

The present disclosure provides methods for forming segmented vias, or through holes, in multi-layer printed circuit board. A multilayer PCB can be a chip substrate, a motherboard, a backplane, a backpanel, a centerplane, a flex or rigid flex circuit. The present disclosure is not restricted to use in PCBs. A via structure can be a plated through hole (PTH) used for transmitting electrical signals from one conducting layer to another. A plated via structure can also be a component mounting hole for electrically connecting an electrical component to other electrical components on the PCB.

### Overview

The present disclosure provides a method of making a printed circuit board which utilizes a novel catalyst removing process after the plating process. In one example of making the PCB, a core or sub-composite structure is formed and at least one plating resist material (or plating resist) may be selectively deposited on a dielectric layer within the core or sub-composite structure or external to the core or sub-composite structure. Next, one or more through holes are formed through the core or sub-composite structure and the plating resist; and a catalyzing material is applied to an interior surface of the one or more through holes, the interior surface having a laminate portion and a plating resist portion where only the laminate portion is coated with a conductive material. Electroless plating is then applied to the one or more through holes and the catalyzing material is removed from the plating resist portion using a catalyst remover. After removing the removing from the plating resist, electrolytic plating is applied to the one or more through holes and an outer layer circuit on the external conductive layers is formed.

### Common Catalyzing Process in Printed Circuit Board Manufacturing

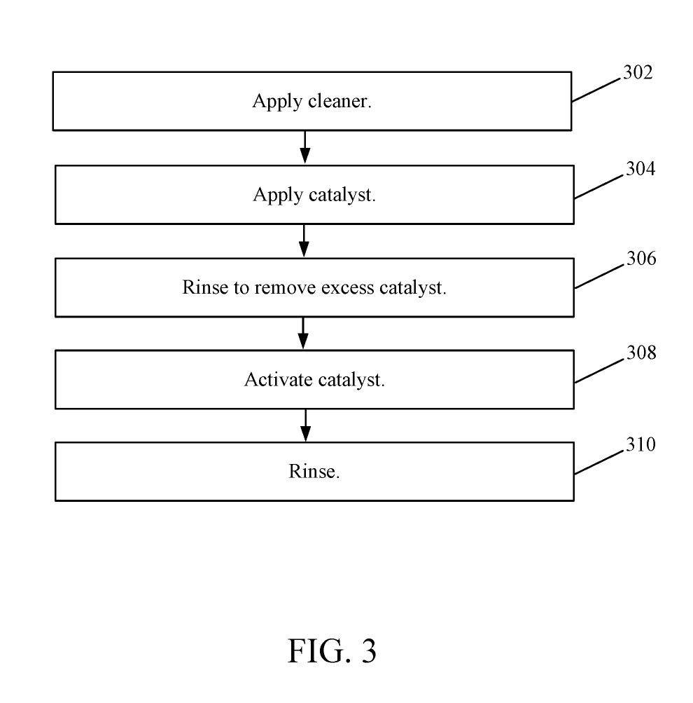

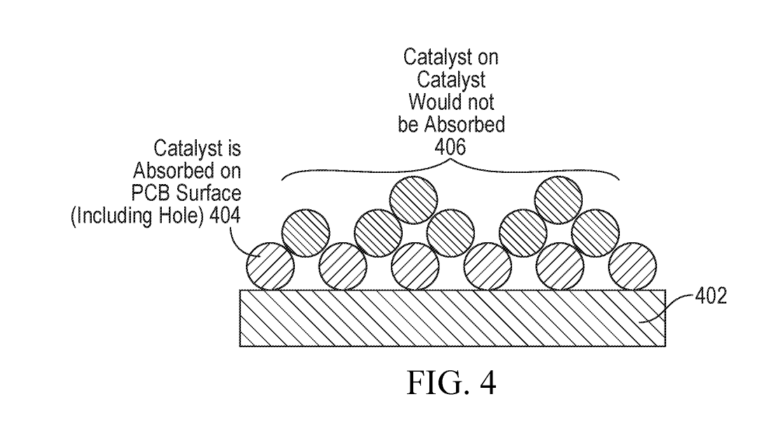

When electroless copper plating is to be performed on through holes for formation of plated through holes or hole portions for formation of via holes, a catalyzing process is usually performed prior to electroless copper plating so as to deposit palladium (Pd), which serves as a plating initiator nucleus for deposition in electroless plating. FIG. 3 illustrates a common catalyzing process utilized in printed circuit board manufacturing. After the drilling of the through holes and the substrate, the resist surfaces are etched to increase adhesion thereto of a subsequently applied catalytic layer and electroless metal layer. Next, a cleaner may be applied 302. The cleaner may be an acid or alkaline cleaner, for example. Next a catalyst may be applied 304 and the PCB rinsed 306 to remove any excess catalyst. FIG. 4 illustrates a PCB surface 402 having excess catalyst on the surface of the PCB. As shown, a first set of catalyst particles (or catalyst) 404 near from PCB surface 402 is absorbed into the PCB surface 402, as well as the through hole, and a second set of catalyst particles (or catalyst) 406 away from the PCB surface 402 are not absorbed. Returning to FIG. 3, the surfaces of the PCB, including through hole surfaces and resist surfaces, are then subjected to processes known in the art which activate the surfaces for acceptance of a conductive material 308. The PCB is then rinsed 310 to remove the excess catalyst 406 as shown in FIG. 4. The PCB is then treated to apply a metallized layer on those surfaces thereof, including through hole surfaces, active toward such metallization.

### Removal of Excess Catalyst During Formation of PCB

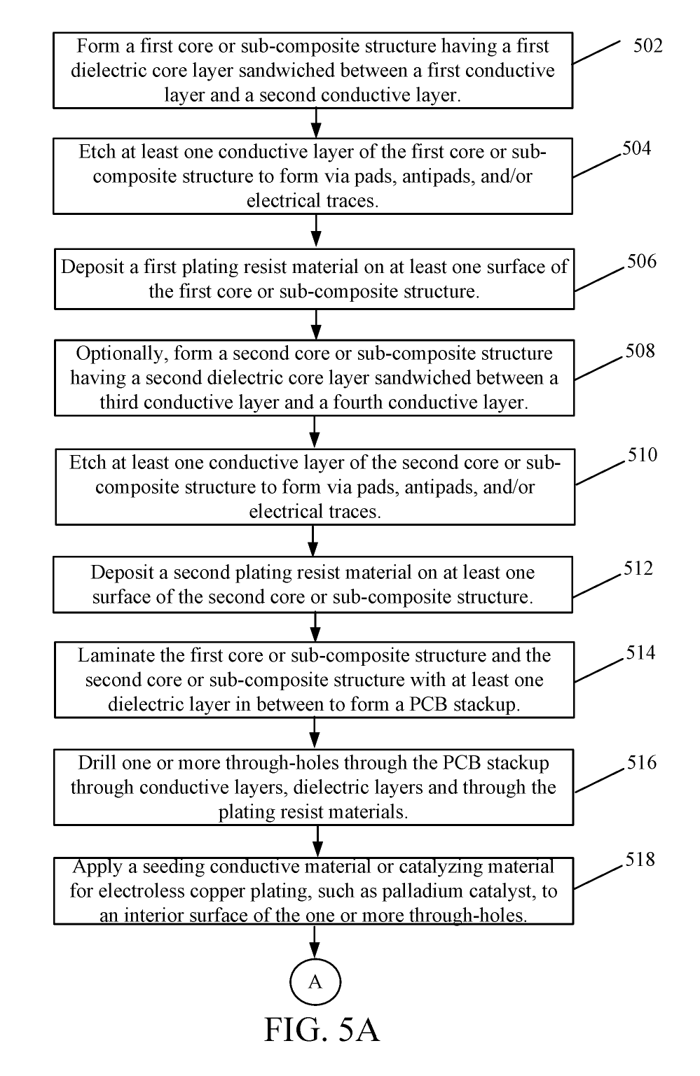

FIG. 5 (comprising FIGS. 5A and 5B) illustrates a method for forming a PCB having one or more segmented vias, according to one aspect of the present disclosure. First, a first core or sub-composite structure, having a first dielectric core layer sandwiched between a first conductive layer and a second conductive layer, may be formed 502. At least one conductive layer of the first core or sub-composite structure may be etched to form via pads, antipads, and/or electrical traces 504. For instance, such etching may serve to form electrical paths to/from points where vias are to be formed. A first plating resist material may then be deposited on at least one surface of the first core or sub-composite structure 506, if a plating resist material is embedded into the core.

Optionally, a second core or sub-composite structure, having a second dielectric core layer sandwiched between a third conductive layer and a fourth conductive layer, may be formed 508. At least one conductive layer of the second core or sub-composite structure may be etched to form via pads, antipads, and/or electrical traces 510. For instance, such etching may serve to form electrical paths to/from points where vias are to be formed. A second plating resist material may then be deposited on at least one surface of the second core or sub-composite structure 512. The process of forming additional cores or sub-composite structures 508-512 may be repeated as necessary.

The first core or sub-composite structure, as well as any optionally additional corresponding composite structures, such as the second core or sub-composite structure, may then be laminated with at least one dielectric layer in between, forming a PCB stackup 514. One or more through holes may be drilled through the PCB stackup through conductive layers, dielectric layers and through the plating resist materials (or plating resist) 516. Next, a seeding conductive material or a catalyzing material for electroless copper plating, such as palladium catalyst, may be applied to the one or more through holes 518 and then electroless copper may be applied 520.

After the electroless plating, excess catalyst on the surface of the plating resist materials (or plating resist) may be removed 522. The catalyst may then be removed using a catalyst remover, such as an acidic solution that includes at least nitrite or nitrite ion and halogen ion, or the catalyst remover may be an etchant for plating resist, such as alkaline permanganate compound solution or plasma gas comprising at least one of oxygen, nitrogen, argon and tetrafluoromethane, or a mixture of at least two of these gasses. After removal of the excess catalyst, electrolytic plating may then be applied to the one or more through holes 524. Next, the outer layer circuit or signal traces may then be formed on the external conductive layers 526. That is, the etching of paths on the conductive foils/layers of the core structure.

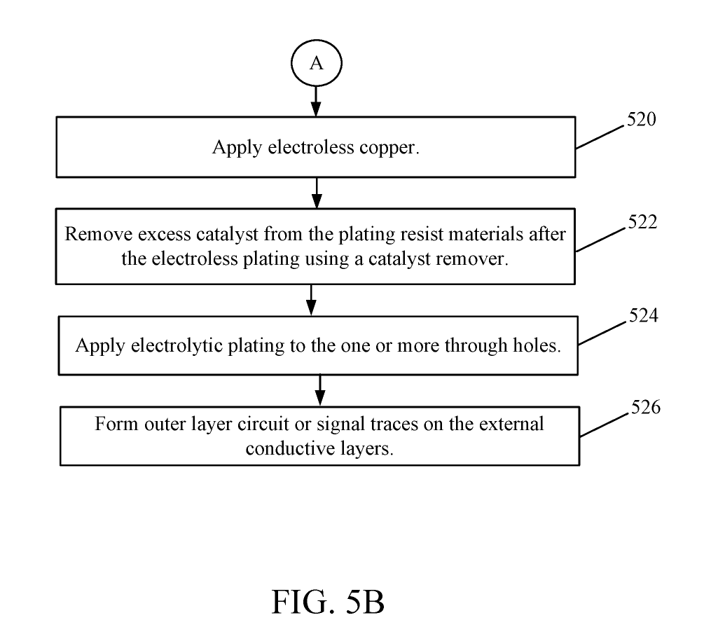

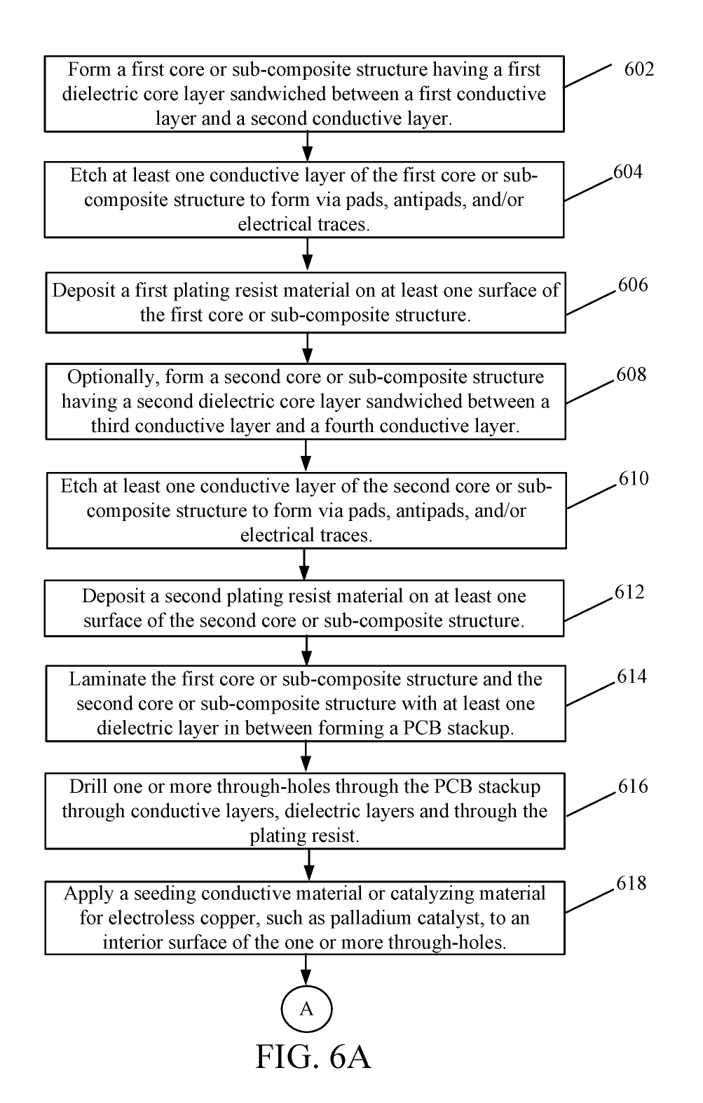

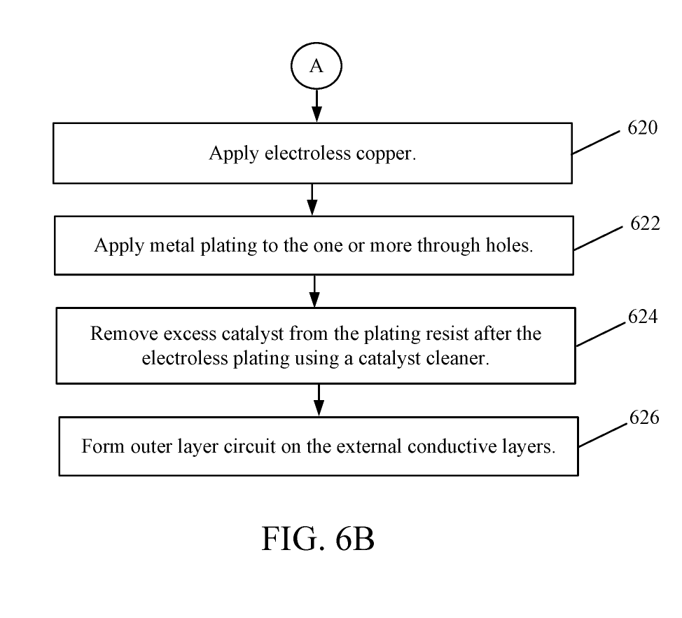

FIG. 6 (comprising FIGS. 6A and 6B) illustrates a method for forming a PCB having one or more segmented vias, according to one aspect of the present disclosure. First, a first core or sub-composite structure, having a first dielectric core layer sandwiched between a first conductive layer and a second conductive layer, may be formed 602. At least one conductive layer of the first core or sub-composite structure may be etched to form via pads, antipads, and/or electrical traces 604. For instance, such etching may serve to form electrical paths to/from points where vias are to be formed. A first plating resist material (or plating resist) may then be deposited on at least one surface of the first core or sub-composite structure 606.

Optionally, a second core or sub-composite structure, having a second dielectric core layer sandwiched between a third conductive layer and a fourth conductive layer, may be formed 608. At least one conductive layer of the second core or sub-composite structure may be etched to form via pads, antipads, and/or electrical traces 610. For instance, such etching may serve to form electrical paths to/from points where vias are to be formed. A second plating resist material (or plating resist) may then be deposited on at least one surface of the second core or sub-composite structure 612. The process of forming additional cores or sub-composite structures 608-612 may be repeated as necessary.

The first core or sub-composite structure, as well as any optionally additional corresponding composite structures, such as the second core or sub-composite structure, may then be laminated with at least one dielectric layer in between, forming a PCB stackup 614. One or more through holes may be drilled through the PCB stackup through conductive layers, dielectric layers and through the plating resist materials (or plating resist) 616. Next, a seeding conductive material or catalyzing material for electroless copper plating, such as palladium catalyst, may be applied to the one or more through holes 618 and then electroless copper is applied 620.

Electrolytic plating may then be applied to the one or more through holes 622. After the electrolytic plating, excess catalyst on the surface of the plating resist may be removed 624. The catalyst may be removed using a catalyst cleaner or remover, such as an acidic solution that includes at least nitrite or nitrite ion and halogen ion, or the catalyst remover may be an etchant for plating resist, such as alkaline permanganate compound solution or plasma gas comprising at least one of oxygen, nitrogen, argon and tetrafluoromethane, or a mixture of at least two of these gasses. After removal of the excess catalyst, the outer layer circuit or signal traces may then be formed 626. That is, the etching of paths on the conductive foils/layers of the core structure. According to one embodiment, the catalyst cleaning process may be applied after circuit or trace formation instead of the catalyst cleaning before circuit or trace formation.

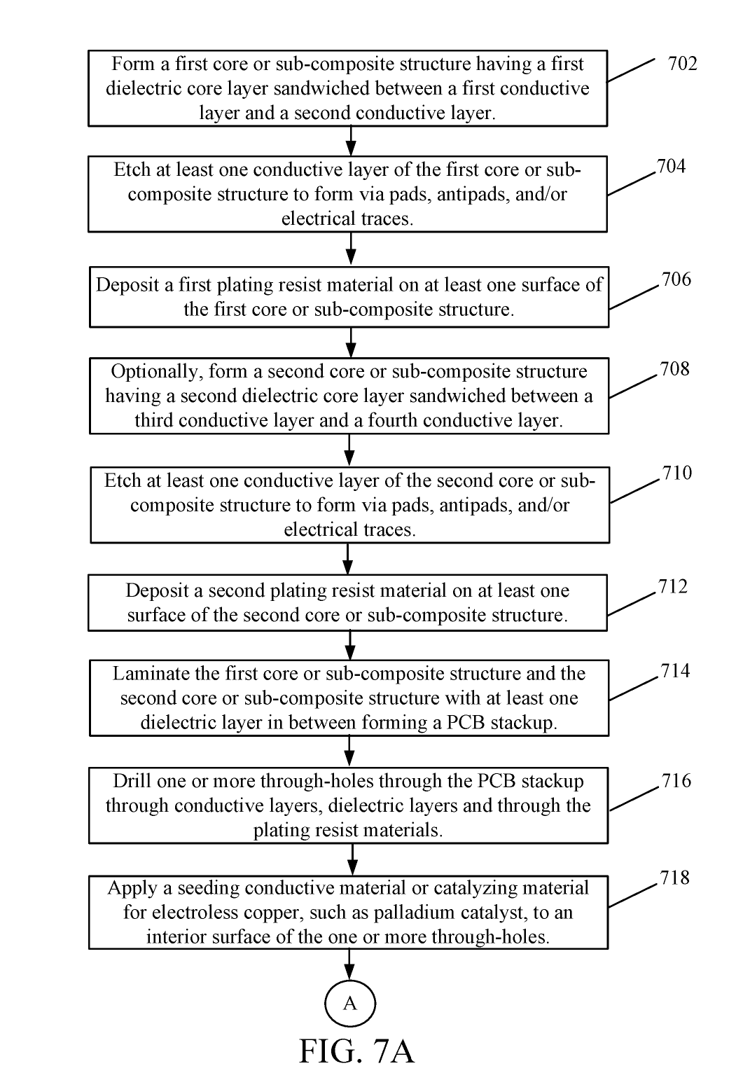

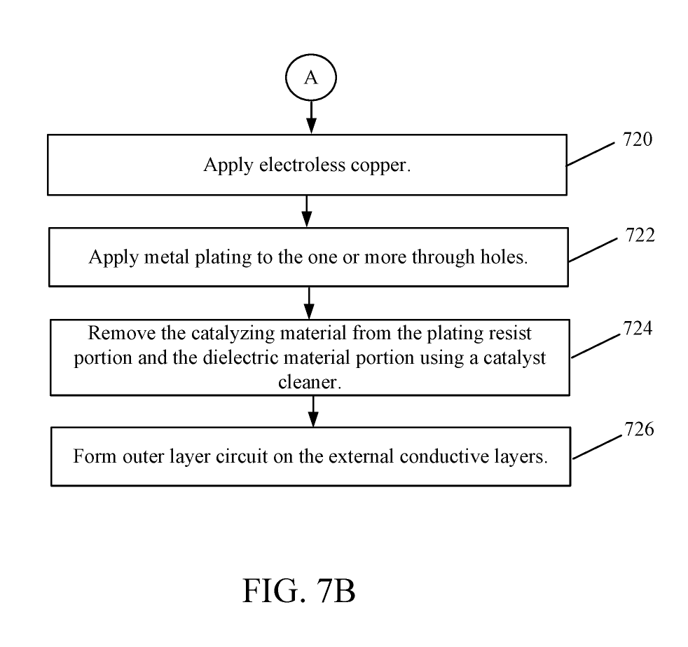

FIG. 7 (comprising FIGS. 7A and 7B) illustrates a method for forming a PCB having one or more segmented vias, according to one aspect of the present disclosure. First, a first core or sub-composite structure, having a first dielectric core layer sandwiched between a first conductive layer and a second conductive layer, may be formed 702. At least one conductive layer of the first core or sub-composite structure may be etched to form via pads, antipads, and/or electrical traces 704. For instance, such etching may serve to form electrical paths to/from points where vias are to be formed. A first plating resist material (or plating resist) may then be deposited on at least one surface of the first core or sub-composite structure 706.

Optionally, a second core or sub-composite structure, having a second dielectric core layer sandwiched between a third conductive layer and a fourth conductive layer, may be formed 708. At least one conductive layer of the second core or sub-composite structure may be etched to form via pads, antipads, and/or electrical traces 710. For instance, such etching may serve to form electrical paths to/from points where vias are to be formed. A second plating resist material may then be deposited on at least one surface of the second core or sub-composite structure 712. The process of forming additional cores or sub-composite structures 708-712 may be repeated as necessary.

The first core or sub-composite structure, as well as any optionally additional corresponding composite structures, such as the second core or sub-composite structure, may then be laminated with at least one dielectric layer in between, forming a PCB stackup 714. One or more through holes may be drilled through the PCB stackup through conductive layers, dielectric layers and through the plating resist materials (first and second plating resist materials) 716. Next, a seeding conductive material or catalyzing material for electroless copper plating, such as palladium catalyst, may be applied to the one or more through holes 718 and then electroless copper may be applied 720.

Electrolytic plating may then be applied to the one or more through holes 722. After the electrolytic plating, excess catalyst on the surface of the plating resist material (or plating resist) may be removed 724. The outer layer circuit or signal traces may then be formed 724. That is, the etching of paths on the conductive foils/layers of the core structure. Finally, the catalyzing material may be removed using a catalyst remover, such as an acidic solution that includes at least nitrite or nitrite ion and halogen ion, or the catalyst remover may be an etchant for plating resist, such as alkaline permanganate compound solution or plasma gas comprising at least one of oxygen, nitrogen, argon and tetrafluoromethane, or a mixture of at least two of these gasses.

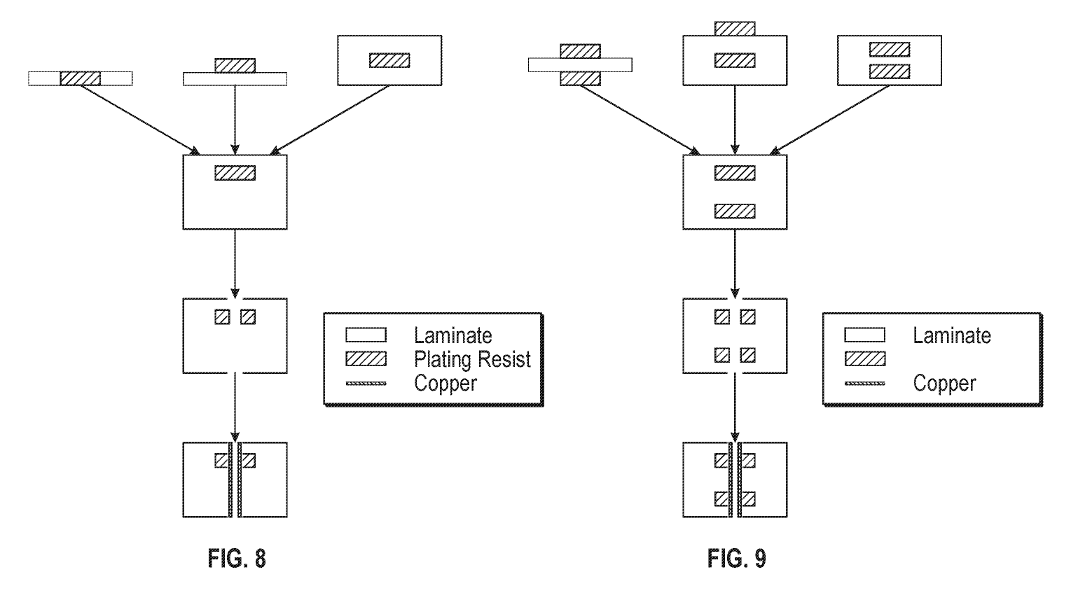

FIG. 8 illustrates cross-sectional view of a PCB stackup having a single plating resist while FIG. 9 illustrates cross-sectional view of a PCB stackup having more than one plating resist.

Cross-Sectional View of Through-Hole with Residual Catalyst Deactivated

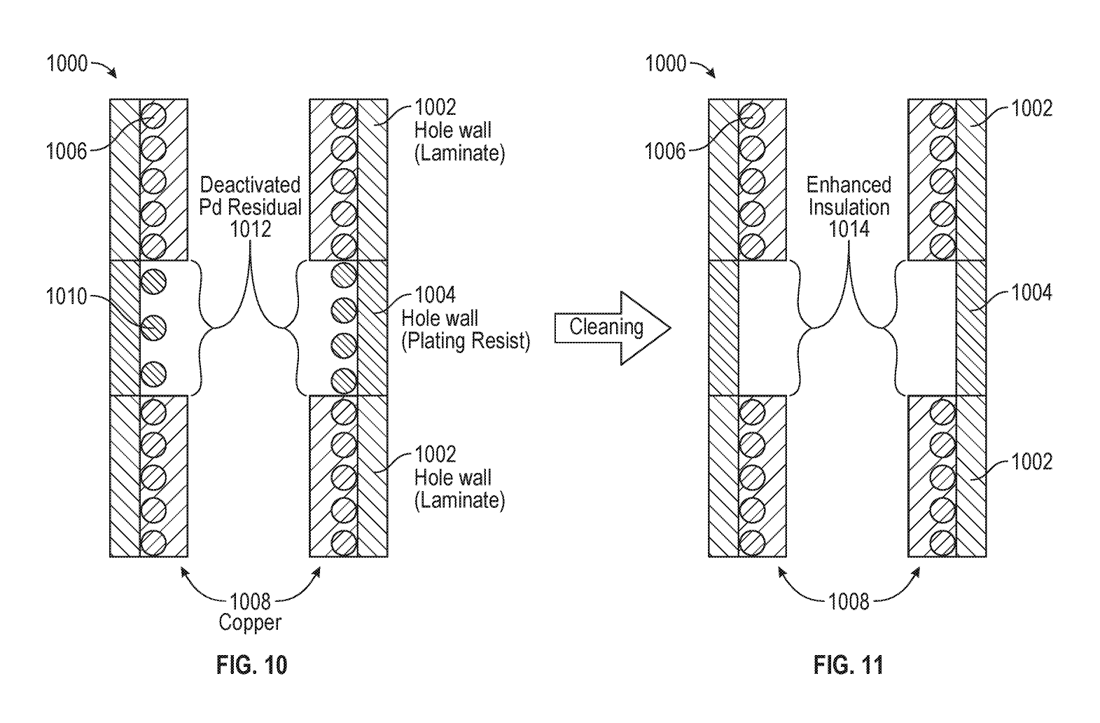

FIG. 10 illustrates a cross-sectional view of a through hole in a printed circuit board where residual catalyst is deactivated. The subtractive process or the additive process may be used during the formation of the printed circuit board as known in the art.

As shown in FIG. 10, the wall of the through hole 1000 may be comprised of a laminate portion 1002 and a plating resist portion 1004. The laminate portion 1002 may have a first set of catalyst particles (or catalyst or catalyzing material) 1006 which is activated for conductive material deposition, such as copper 1008.

A second set of catalyst particles (or catalyst) 1010 located on the plating resist portion 1004 can be deactivated 1012. Although these catalyst particles (or catalyst) 1010 can be deactivated or made inert, there is still catalyst that remains on the surface after plating which could cause poor insulation (high potential, migration) and burly plating.

Cross-Sectional View of Through-Hole with Residual Catalyst Removed

FIG. 11 illustrates the cross-sectional view of the through hole in a printed circuit board of FIG. 10 where the residual catalyst is removed. As described above, the subtractive process or the additive process may be used during the formation of the printed circuit board as known in the art.

As shown in FIG. 11, the wall of the through hole 1000 may be comprised of a laminate portion 1002 and a plating resist portion 1004. As described above, the laminate portion 1002 may have a first set of catalyst particles (or catalyst) 1006 which are activated for acceptance of a conductive material, such as copper 1008.

The second set of catalyst particles (or catalyst) 1010 shown in FIG. 10 located on the plating resist portion 1004 may be removed by cleaning to enhance insulation of the PCB 1014. The catalyst can be removed using a remover such as an acidic solution that includes at least nitrite or nitrite ion and halogen ion. The catalyst remover may be an etchant for plating resist, such as alkaline permanganate compound solution or plasma gas comprising at least one of oxygen, nitrogen, argon and tetrafluoromethane.

In the foregoing specification, embodiments of the invention have been described with reference to numerous specific details that may vary from implementation to implementation. The specification and drawings are, accordingly, to be regarded in an illustrative rather than a restrictive sense. The invention is intended to be as broad as the appended claims, including all equivalents thereto.

Those skilled in the art would further appreciate that the various illustrative logical blocks, modules, circuits, and algorithm steps described in connection with the embodiments disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system.

While certain exemplary embodiments have been described and shown in the accompanying drawings, it is to be understood that such embodiments are merely illustrative of and not restrictive on the broad invention, and that this invention not be limited to the specific constructions and arrangements shown and described, since various other modifications may occur to those ordinarily skilled in the art.

1. A method for making a printed circuit board having a segmented plated through hole, comprising:
forming a core or sub-composite structure;
selectively depositing at least one plating resist on a dielectric layer within the core or sub-composite structure or external to the core or sub-composite structure;
forming one or more through holes through the core or sub-composite structure and the plating resist; and
applying a catalyzing material to an interior surface of the one or more through holes, the interior surface having a laminate portion and a plating resist portion where only the laminate portion is coated with a conductive material;
applying electroless plating to the one or more through holes;
removing the catalyzing material from the plating resist portion using a catalyst remover;
applying electrolytic plating to the one or more through holes; and
forming an outer layer circuit on the external conductive layers.

2. The method of claim 1, wherein the catalyzing material is palladium or a palladium derivative.

3. The method of claim 1, wherein the catalyst remover is an acidic solution and wherein the acidic solution includes at least nitrite or nitrite ion and halogen ion.

4. The method of claim 1, wherein the catalyst remover is an etchant for plating resist.

5. The method of claim 4, wherein the etchant is an alkaline permanganate compound solution.

6. The method of claim 5, wherein the etchant is plasma gas.

7. The method of claim 6, wherein the plasma gas includes at least one of oxygen, nitrogen, argon and tetrafluoromethane.

8. A method for making a printed circuit board having a segmented plated through hole, comprising:
forming a core or sub-composite structure;
selectively depositing at least one plating resist on a dielectric layer within the core or sub-composite structure or external to the core or sub-composite structure;
forming a through hole through the core or sub-composite structure and the plating resist;
applying a catalyzing material to an interior surface of the one or more through holes, the interior surface having a laminate portion and a plating resist portion where only the laminate surface is to be coated with a conductive material
applying metal plating to the one or more through holes;
removing the catalyzing material from the plating resist portion using a catalyst remover; and
forming an outer layer circuit on the conductive layers of the first core.

9. The method of claim 8, wherein the catalyzing material is palladium or a palladium derivate.

10. The method of claim 9, wherein the catalyst remover is an acidic solution and wherein the acidic solution includes at least nitrite or nitrite ion and halogen ion.

11. The method of claim 8, wherein the catalyst remover is an etchant for plating resist.

12. The method of claim 11, wherein the etchant is an alkaline permanganate compound solution.

13. The method of claim 11, wherein the etchant is plasma gas and wherein the plasma gas includes at least one of oxygen, nitrogen, argon and tetrafluoromethane.

14. A method for making a printed circuit board having a segmented plated through hole, comprising:
forming a core or sub-composite structure;
selectively depositing at least one plating resist on a dielectric layer within the core or sub-composite structure or external to the core or sub-composite structure;
forming a through hole through the core or sub-composite structure and the plating resist; and
applying a catalyzing material to an interior surface of the one or more through holes, the interior surface having a laminate portion and a plating resist portion where the laminate surface is to be coated with a conductive material and the plating resist portion is not to be plated with a conductive material;
applying metal plating to the one or more through holes;
forming an outer layer circuit on the conductive layers of the first core; and
removing the catalyzing material from the plating resist portion and dielectric material surface using a catalyst remover.

15. The method of claim 14, wherein the catalyzing material is palladium or a palladium derivate.

16. The method of claim 14, wherein the catalyst remover is an acidic solution.

17. The method of claim 16, wherein the acidic solution includes at least nitrite or nitrite ion and halogen ion.

18. The method of claim 14, wherein the catalyst remover is an etchant for plating resist.

19. The method of claim 18, wherein the etchant is an alkaline permanganate compound solution.

20. The method of claim 19, wherein the etchant is plasma gas and wherein the plasma gas includes at least one of oxygen, nitrogen, argon and tetrafluoromethane.
